(19) United States
(12) Patent Application Publication
(10) Pub. No.: US 2009/0229118 A1
(43) Pub. Date: Sep. 17, 2009

(54) Electronics Assembly Machine with Wireless Communication Nozzle

(76) Inventor: Paul R. Haugen, Bloomington, MN (US)

Correspondence Address: Christopher R. Christenson;WESTMAN, CHAMPLIN & KELLY, P.A., Suite 1400, 900 Second Avenue South, Minneapolis, MN, 55402-3319, US

(21) Appl. No.: 12/049,685

(22) Filed: Mar. 17, 2008

(51) Int. Cl. H05K 13/04; H05K 3/30; G08B 1/08

(52) U.S. Cl. 29/740; 340/674; 340/693.5; 340/693.1

(57) ABSTRACT

A pick and place machine for placing components upon a workpiece includes a placement head, a robotic system and at least one detachable nozzle. The robotic system is configured to generate relative movement between the placement head and the workpiece. The detachable nozzle is coupled to the placement head and includes wireless communication circuitry. A detachable nozzle having wireless is communication abilities is also disclosed.

### COPYRIGHT RESERVATION

A portion of the disclosure of this patent document contains material which is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### BACKGROUND

Electronics assembly machines, such as pick and place machines, are generally used to manufacture electronic circuit boards. A blank printed circuit board is usually supplied to the pick and place machine, which then picks electronic components from component feeders, and places such components upon the board. The components are held upon the board temporarily by solder paste or adhesive until a subsequent step in which the solder paste is melted, or the adhesive is fully cured.

Pick and place machine operation is challenging. Since machine speed corresponds with throughput, the faster the pick and place machine runs, the less costly the manufactured board. Additionally, placement accuracy is extremely important. Many electrical components, such as chip capacitors and chip resistors are relatively small and must be accurately placed on equally small placement locations. Other components, while larger, have a significant number of leads or conductors that are spaced from one another at a relatively fine pitch. Such components must also be accurately placed to ensure that each lead is placed upon the proper pad. Thus, not only must the machine operate extremely fast, but it must also place components extremely accurately

Electronics assembly is a critical process. A typical printed circuit board may contain hundreds of individual electronic components each of which has between two and sometimes many individual contact points. If a single pad of a single component is not properly electrically coupled to its respective pad on the circuit board, operation of the entire assembled device may be frustrated. Accordingly, the electronics assembly industry provides significant resources, both in terms of capital equipment and technician time for the process of inspecting assembled printed circuit boards and/or repairing defective boards. Automated optical inspection machines are available that can visually inspect each and every mounted component to help ensure that the assembly step has been performed correctly for every component on the circuit board prior to the permanent fixation of the components upon the board. Permanent fixation of the components upon the board can be in the form of providing the circuit board to a wave solder machine, reflowing solder paste in an oven or curing uncured conductive adhesive.

A vast number of variables can affect placement efficacy. Many variables with the respect to the pick and place machine, itself, can affect the ability of the machine to reliably pick a component from a component feeder, accurately sense a position of a component on a nozzle, move the component to a placement location, correct the orientation of the component prior to placement on the circuit board, and/or place the component upon the circuit board. Variables include vacuum strength, actuation timing, machine wear or inaccuracies in each of x, y, and z directions, accuracy of encoders of the pick and place machine in the x, y, and z direction, deviations from flatness of the printed circuit board, pressure of the nozzle upon the board as the component is placed on the workpiece, as well as many other variables. Further, there are a number of variables that can affect placement efficacy which are not related to the pick and place machine itself. For example, the ability of solder paste and/or uncured adhesive to temporarily adhere a placed component may change with temperature, barometric pressure, or even relative humidity. Moreover, different batches of solder paste may have different viscosities and/or may be deposited by a solder paste printing machine differently. Variability in the application of materials such as solder paste and adhesive paste prior to the placement operation can cause these materials to inadvertently come into contact with the placement head causing the vacuum suction line to clog or to improperly adhere the component to the nozzle. Also, a major cause of pick and place errors is setup error, which occurs when an incorrect feeder, program, nozzle or parameter is inadvertently used by the technician responsible in the setup of the machine.

To date, the art has responded to the conflicts between the extreme speed of a pick and place machine and the multiplicity of variables affecting placement efficacy with powerful inspection tools. As set forth above, automated optical inspection machines are typically placed after a pick and place machine in order to optically inspect placed components. More recently, optical inspection hardware and techniques have been migrated to the pick and place machine itself such that the placement of each component can be evaluated immediately after the component is placed. However, given that the pick and place machine head often must move in different directions relatively quickly, any mass added to the pick and place machine head will necessarily increase inertia of the pick and place machine head, which increased inertia may decrease overall throughput of the pick and place machine. In addition, adding sensors to the placement will add to the amount of cabling required to be run to the placement head. Since the cabling to the placement head is required to flex during placement head motion, the reliability of the cabling as well as the extra inertia required to move the cable becomes problematic.

Other attempts at improving the placement efficacy have centered on the operation of the nozzle used to perform the pick and place operation. For example, U.S. Pat. Nos. 5,742,396 and 6,393,336 provide an apparatus detecting a clogged nozzle. U.S. Pat. No. 6,100,922 provides a nozzle that is shaped to assist in the illumination of the picked component. U.S. Pat. No. 5,064,235 provides an apparatus that extends the function of the pick and place nozzle to test the conductance of the picked component.

Providing the electronics assembly industry with additional data relative to pick and place machine operation, and/or placement efficacy without requiring significant increases in placement head inertia, or significant retrofitting efforts, would represent a significant benefit.

### SUMMARY

A pick and place machine for placing components upon a workpiece includes a placement head, a robotic system and at least one detachable nozzle. The robotic system is configured to generate relative movement between the placement head and the workpiece. The detachable nozzle is coupled to the placement head and includes wireless communication circuitry. A detachable nozzle having wireless communication abilities is also disclosed.

### BRIEF DESCRIPTION OF THE DRAWINGS

FIG. 1 is a diagrammatic view of a Cartesian pick and place machine with which embodiments of the invention can be practiced.

FIG. 2 is a diagrammatic plan view of a turret pick and place machine with which embodiments of the invention can be practiced.

FIG. 3 (3a-3c) is a diagrammatic view of a detachable nozzle having wireless communication in accordance with an embodiment of the present invention.

FIG. 4 is a diagrammatic view of nozzle identification in accordance with an embodiment of the present invention.

FIG. 5 is a diagrammatic view of a nozzle exchange reservoir in accordance with an embodiment of the present invention.

FIG. 6 is a diagrammatic view of a power module of a detachable nozzle having wireless communication in accordance with an embodiment of the present invention.

FIG. 7 is a diagrammatic view of wireless communication module of a detachable nozzle having wireless communication in accordance with an embodiment of the present invention.

FIG. 8 is a diagrammatic view of measurement circuitry of a detachable nozzle having wireless communication in accordance with an embodiment of the present invention.

FIG. 9 is a diagrammatic view of a detachable nozzle having wireless communication in accordance with another embodiment of the present invention.

FIG. 10 is a diagrammatic view of output circuitry of a detachable nozzle having wireless communication in accordance with an embodiment of the present invention.

FIG. 11 is a diagrammatic view of still another detachable nozzle having wireless communication in accordance with an embodiment of the present invention.

### DETAILED DESCRIPTION OF ILLUSTRATIVE EMBODIMENTS

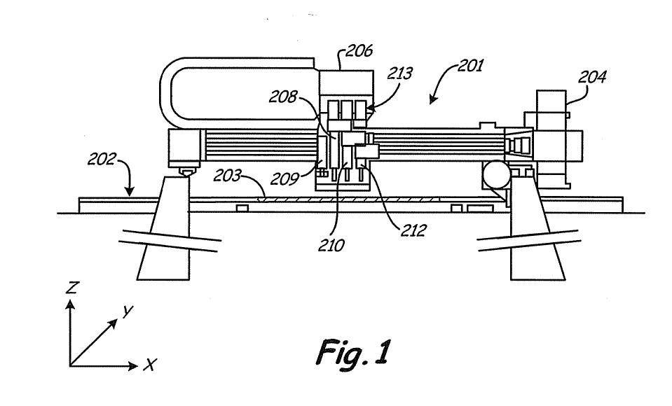

FIG. 1 is a diagrammatic view of an exemplary Cartesian pick and place machine 201 with which embodiments of the present invention are applicable. Pick and place machine 201 receives a workpiece, such as circuit board 203, via transport system or conveyor 202. Placement head 206 then obtains one or more electrical components to be mounted upon circuit board 203 from component feeders (not shown) and moves in x, y and z directions to place the component in the proper orientation at the proper location upon circuit board 203. Placement head 206 may include multiple nozzles 208, 210, 212 to pick multiple components. Some pick and place machines may employ a placement head that moves over a stationary camera to image the components) in order to ascertain component location and orientation upon each nozzle. Placement head 206 may also include a downwardly looking camera 209, which is generally used to locate fiducial marks upon circuit board 203 such that the relative location of placement head 206 with respect to circuit board 203 can be readily calculated.

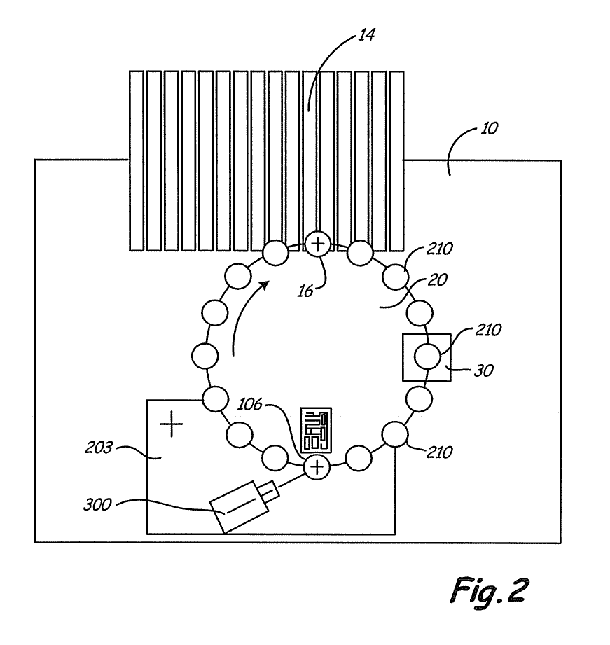

FIG. 2 is a diagrammatic view of an exemplary rotary turret pick and place machine 10 with which embodiments of the present invention are also applicable. Machine 10 includes some components that are similar to machine 201 and like components are numbered similarly. For turret pick and place machine 10, circuit board 203 is loaded via a conveyor onto an x-y stage (not shown). Attached to main turret 20 are nozzles 210 that are disposed at regular angular intervals around the rotating turret. During each pick and placement cycle, turret 20 indexes an angular distance equal to the angular distance between adjacent placement nozzles 210. After turret 20 rotates into position and circuit board 203 is positioned by the x-y stage, a placement nozzle 210 obtains a component from a component feeder 14 at a defined pick point 16. During this is same interval, another nozzle 210 places a component onto circuit board 203 at a preprogrammed placement location 106. Additionally, while turret 20 pauses for the pick and place operation, upward looking camera 30 acquires and image of another component, which provides alignment information for that component. This alignment information is used by pick and place machine 10 to position circuit board 203 when placement nozzle 210 is positioned several steps later to place the component. After the pick and place cycle is complete, turret 20 indexes to the next angular position and circuit board 203 is repositioned in x-y direction(s) to move the placement location to position which corresponds to the placement location 106.

Embodiments of the present invention generally provide an electronics assembly machine having at least one detachable nozzle that communicates wirelessly. The use of wireless communication facilitates automatic picking of the wireless nozzle from a nozzle exchange reservoir; using the wireless nozzle by virtue of one or more wireless communication signals; and finally replacing the wireless nozzle back into a nozzle exchange reservoir. As used herein, a wireless communication signal includes any signal sent from or to the wireless nozzle without the use of electrical conductors. Examples of wireless communication include radio-frequency (RF) communication, optical communication, and even pneumatic communication.

Utilization of detachable nozzles in electronics assembly machines is known. For example, U.S. Pat. Nos. 4,831,721, 5,201,696 and 6,422,489 provide an apparatus for the replacement of vacuum nozzles. While it is preferred that embodiments of the present invention be generally embodied within a detachable nozzle assembly that can be automatically picked from a nozzle exchange reservoir, utilized, and replaced, it is also contemplated that embodiments of the present invention can be practiced with a nozzle that is manually engaged and/or disengaged to a pick and place machine's placement head. The manner in which the detachable nozzle is coupled to the pick and place machine placement head can also vary. For example, a vacuum, electromagnetism, and/or electromechanical clamping, or any combination thereof can be used to retain the detachable nozzle.

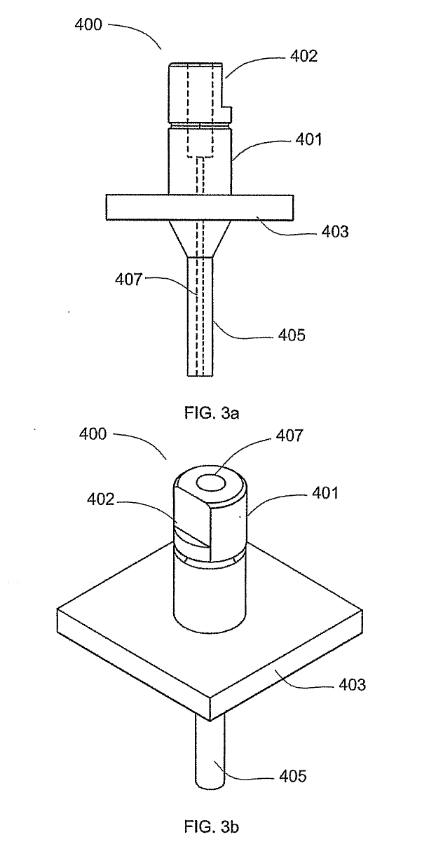

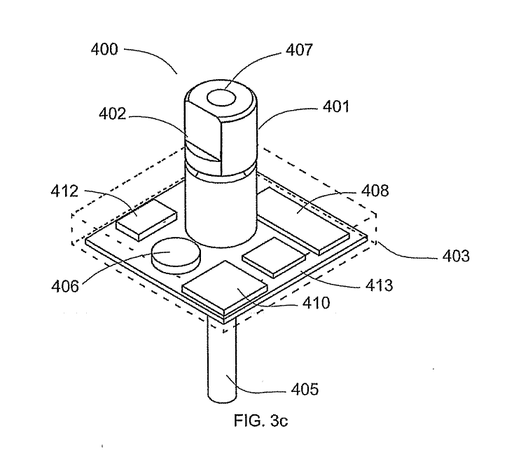

FIGS. 3a and 3b show a diagrammatic view of detachable nozzle 400 in accordance with an embodiment of the present invention. Nozzle 400 includes nozzle body 401 coupled to engagement portion 402. Engagement portion 402 can take any suitable physical form that can be configured to engage and disengage with a pick and place machine's placement head. Preferably, portion 402 is configured so that nozzle 400 can be automatically attached and detached to/from a pick and place machine placement head. The vacuum used to pick up the component is supplied by the pick and place head 206 and is transferred to the tip of the nozzle 405 through an opening 407 that runs the length of nozzle 405. Also, extending from nozzle body 401 is an electronics housing 403 that is configured to be the same shape as a passive reflector found on current state of the art pick and place nozzles to provide background illumination for upward looking alignment cameras.

FIG. 3c shows the internal configuration of electronics housing 403. The nozzle electronics housing 403 contains identification module 404, power module 406, communication module 408, controller 410 and input circuitry 412 mounted on a printed circuit board (PCB) 413. Through PCE 413, the power module 406 is operably coupled to communication circuitry 408, controller 410, and input circuitry 412. Additionally, controller 410 is coupled to communication module 408 and input circuitry 412.

Controller 410 preferably includes a microprocessor and that is configured to execute a plurality of instructions stored in memory disposed within controller 410 or coupled thereto. Additionally, memory can be used to store information related to one or more input signals obtained by nozzle 400. In this manner, nozzle 400 is able to store information related to its operation within a pick and place machine.

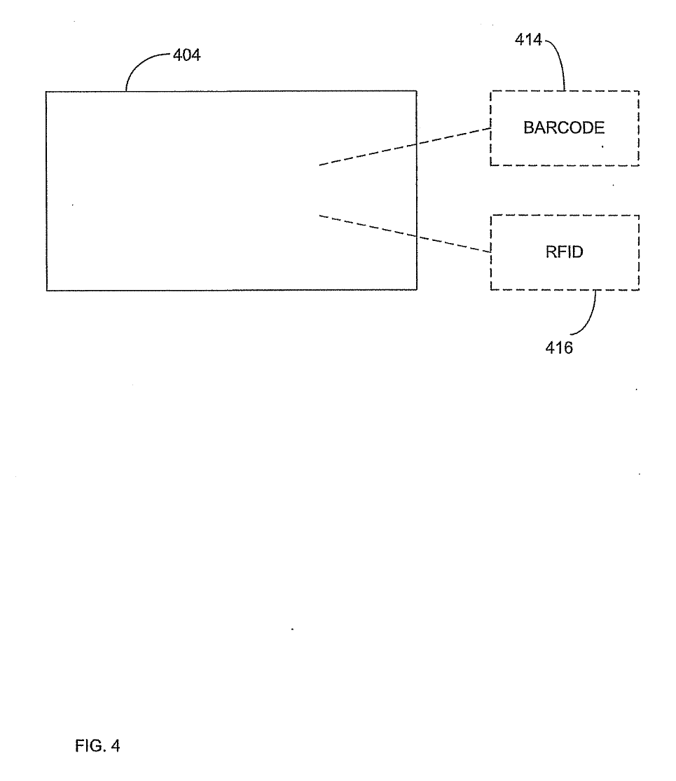

FIG. 4 is a diagrammatic view of identification 404 in greater detail. Specifically, identification 404 is disposed within, or coupled to, nozzle body 401 can include any suitable identification that identifies individual nozzle 400, the capabilities and/or requirements of nozzle 400, or any other suitable information relative to nozzle 400. The physical form in which identification 404 is embodied can vary as well. For example, identification 404 can simply take the form of written indicia. Additionally, and preferably, identification 404 is machine readable identification. For example, machine readable identification can include barcode information 414, and/or radio frequency identification (RFID) information 416. RFID tags are a known technology with which information between a non-powered RFID tag and an RFID reader can be exchanged when the reader is brought into relatively close proximity to the RFID tag. Thus, it is contemplated that an RFID reader and/or barcode reader be provided with, or integrated with a placement head of a pick and place machine such that the pick and place machine can learn information about nozzle 400 simply by brining the placement head into the proximity of nozzle 400. Thus, as will be described in greater detail below, individual detachable nozzles can be tailored to specific functions and their identification 404 can provide an indication of their individual requirements and/or abilities.

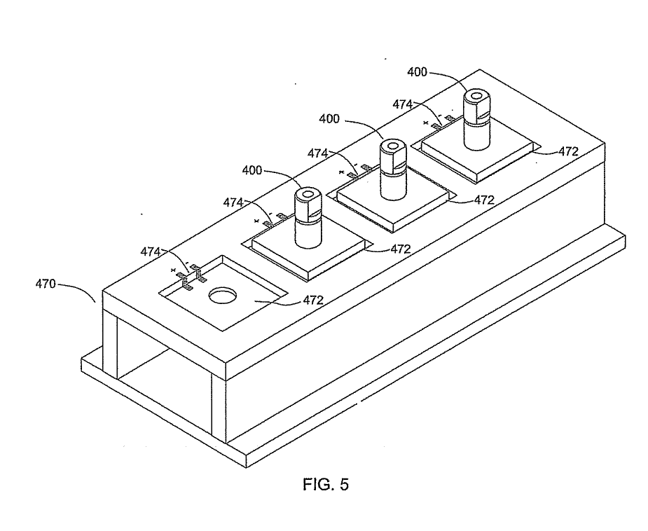

FIG. 5 is a diagrammatic view of nozzle exchange reservoir 470. The nozzle exchange reservoir is typically located within the pick and place machine 201 within the motion envelope of the pick and place head 206. The nozzle exchange reservoir 470 typically has several nozzle locating features 472 that hold the nozzles 400 in a known position and orientation. An operator will place the nozzles 400 into these locating features 472 prior to the pick and place operation. During operation, the pick and place head is moved into position over a nozzle 400 and lowered to engage a nozzle 470 for use. Nozzles 470 are exchanged whenever a different size or style of component requires placing, or if the nozzle is damaged or otherwise not functioning properly.

In a preferred embodiment of the present invention, electrical contacts 474 are placed in the vicinity of the nozzle locating features 472 so that when a nozzle 470 is placed in the locating feature 472, the electrical contacts 474 engage with contacts (not shown in FIG. 5) on the electronics housing 403 to provide power to recharge the power source 406.

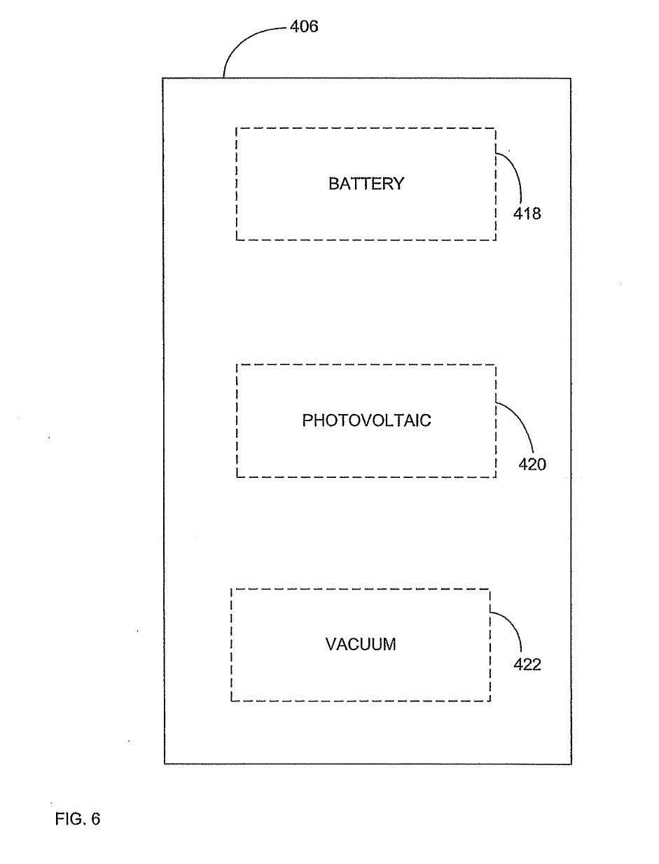

FIG. 6 is a diagrammatic view of power module 406 in accordance with an embodiment of the present invention. Preferably, module 406 includes battery 418. More preferably, battery 418 is a rechargeable battery. In this manner, battery 418 can be recharged using electrical contacts 474 whenever nozzle 400 is maintained within its respective nozzle position in the nozzle exchange reservoir 470. However, embodiments of the present invention can be practiced with non-rechargeable batteries. Power module 406 may also contain photovoltaic cell 420 which, in accordance with known techniques, can generate electricity from electromagnetic illumination. Thus, an illuminator of the pick and place machine can provide additional energy for operation of nozzle 400. Further still, power module 406 may also, or in the alternative, contain vacuum module 422 that is configured to generate electricity based upon airflow through nozzle 400 in response to vacuum generated by the pick and place machine. Further still other energy storage and/or generation sources can be used within power module 406, as appropriate. Power module 406 can also include suitable electronic circuitry to condition, regulate, or otherwise adapt electrical power for utilization by other electrical components.

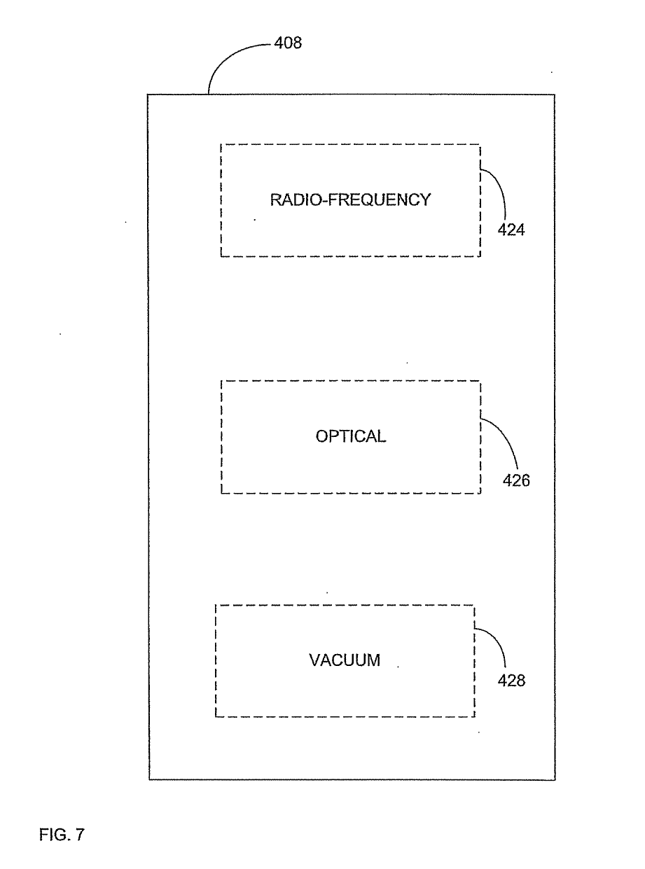

FIG. 7 is a diagrammatic view of wireless communication module 408 in accordance with an embodiment of the present invention. FIG. 7 illustrates that wireless communication module 408 can include one or more different types of wireless communication. For example, wireless communication can include radio-frequency communication 424. RF communication 424 can be in accordance with any suitable standard including the known Bluetooth standard, the Wireless Fidelity (WiFi) communication standard such as IEEE 802.11b or IEEE 802.11g, or any other later-developed WiFi technologies, such as the smart RFID technologies. Certainly, custom RF communication can be used as well. Custom RF communication can include the utilization of any appropriate frequency, and/or information encoding regimes.

Wireless communication module 408 can, in addition or in the alternative, use optical communication techniques. Such optical communication techniques can include the utilization of infrared (IR) communication which is common in devices such as laptop computers and handheld computers.

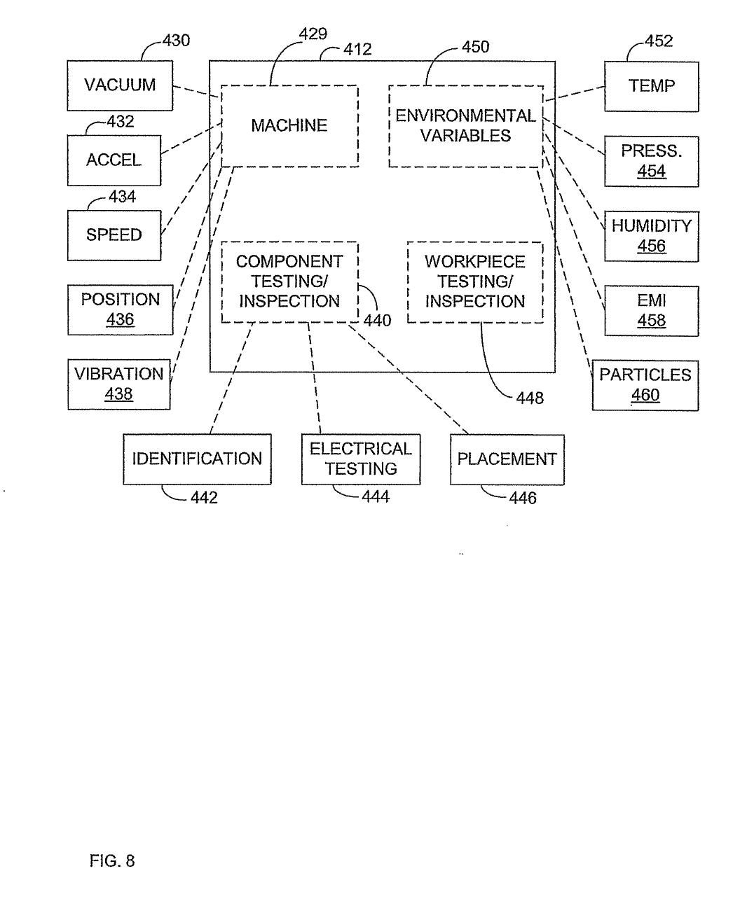

FIG. 8 is a diagrammatic view of input circuitry 412 in accordance with an embodiment of the present invention. Input circuitry 412 can be configured to transducer or otherwise obtain, information relative to any suitable condition, characteristic or parameter of interest within or related to pick and place machine operation. Such parameters can include variables 429 relative to the pick and place machine itself. Such parameters can include information relative to the strength, and clarity of the vacuum 430 required to hold a component on the nozzle. Additionally, machine variables 429 include measurement of acceleration 432 in any suitable direction, such as the x, y, and/or z axis or rotation about the axis of the nozzle. Another important machine variable 429 includes the speed 434 with which the placement head moves. Additionally, yet another machine variable 429 is the positioning 436 of the placement head within the pick and place machine. Another machine variable 429 is any vibration 438 present within the pick and place machine. The utilization of one or more sensors to detect such machine variables 429 allow for the pick and place machine to perform a variety of self diagnostics, and/or determine causes of problems. For example, if a number of defects are produced, the pick and place machine can automatically select a replaceable nozzle 400 having a sensor adapted to sense position 436. This position sensor can be used to independently verify the position of the placement head to determine if the encoders of the pick and place machine are accurately reporting position of the placement head.

Input circuitry 412 can also include components that are configured to measure environmental variables 450 within or proximate the pick and place machine. Such environmental variables include temperature 452, pressure 454 (such as barometric pressure), humidity 456, electromagnetic interference (EMI) 458, electromagnetic charge (EMC) and/or the presence and quantification of particulates 460.

Input circuitry 412 can also include circuits or modules to test or otherwise inspect components placed by the pick and place machine. Such component testing/inspection 440 can include identification 442 of the components. Such identification can be in the form of optical character recognition (OCR) of indicia on the surface of the components by virtue of an image of the component acquired by nozzle 400. Additionally, component testing/inspection 440 can include actual electrical testing 444 of the component. Such electrical testing can include the application of a test voltage or current to two or more test pads of the component, or circuit board, in order to determine whether the component, or circuit board, responds appropriately. Further still, component testing/inspection 440 can include placement inspection 446. Placement inspection 446 can be in the form of a small video camera retained within housing 401 coupled to input circuitry 412. Images of the component acquired by the video camera can be compared with known good placement images to determine whether the placement of the component under test is correct. Certainly, other image processing techniques or inspection regimes can also be used. Input circuitry 412 can also includes circuits or modules to facilitate testing 448 of the circuit board itself.

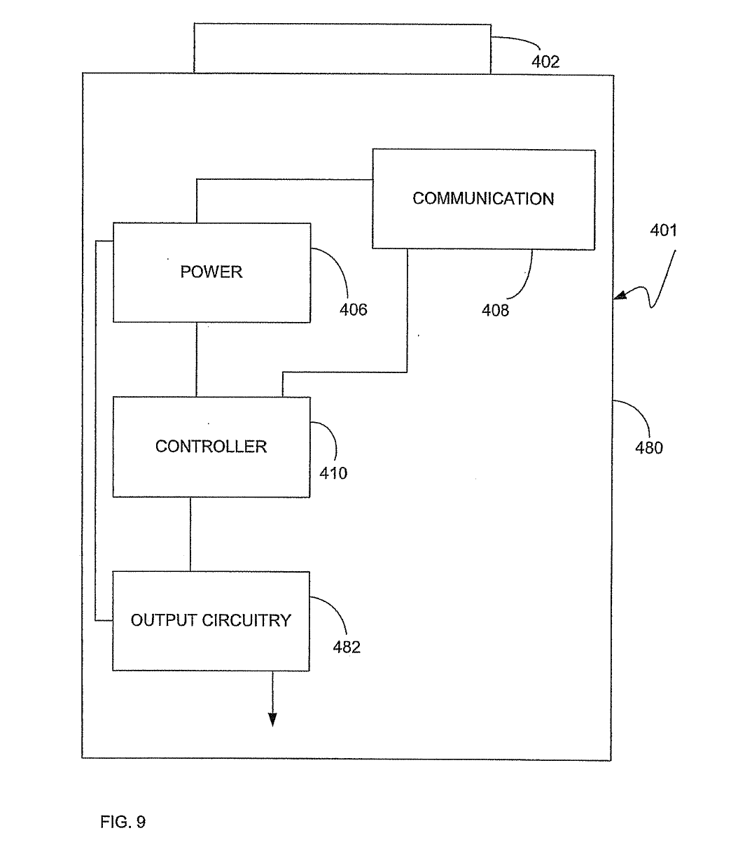

FIG. 9 is a diagrammatic view of another detachable nozzle with wireless communication abilities in accordance with another embodiment of the present invention. Nozzle 480 bears many similarities to nozzle 400 and like components are numbered similarly. The primary difference between nozzle 480 and nozzle 400 is that nozzle 480 includes output circuitry 482 instead of the input circuitry 412 of nozzle 400.

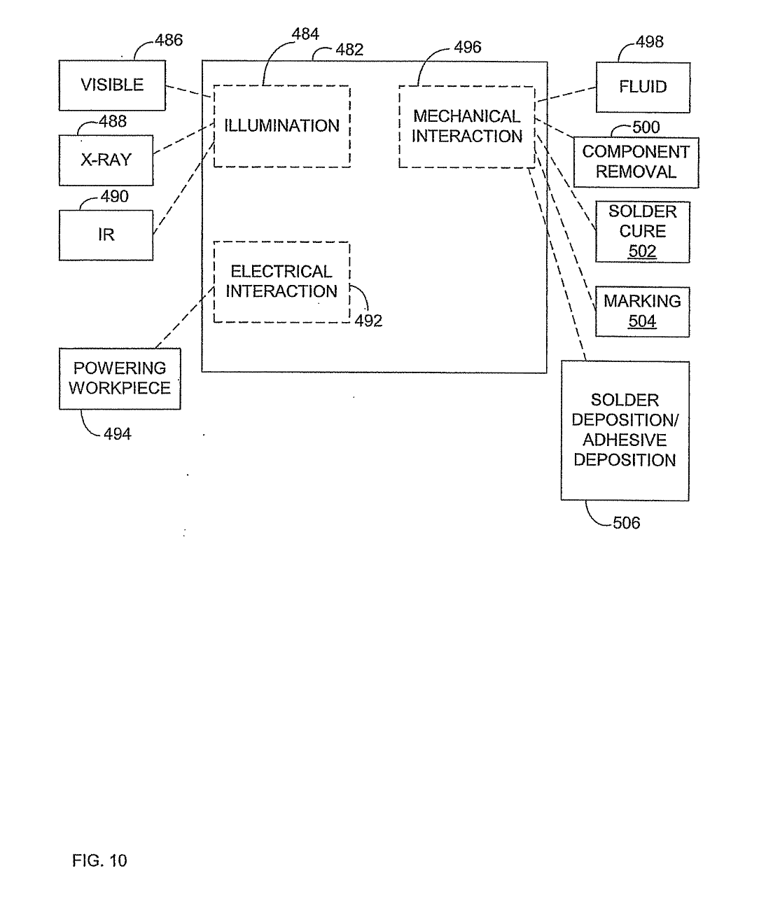

FIG. 10 is a diagrammatic view of output circuitry 482 in accordance with an embodiment of the present invention. Output circuitry 482 can be configured to deliver any suitable physical interaction to a component or workpiece of the pick and place machine. Such physical interaction can include illumination 484, which illumination 484 can include visible illumination 486, x-ray illumination 488, and/or infrared (IR) illumination 490. Additionally, physical interaction can include mechanical interaction 496. Such mechanical interaction 496 can include the delivery of a suitable fluid to the component or circuit board. One example of a suitable fluid may simply be a blast of air to dislodge or otherwise remove debris. Yet another form of mechanical interaction 496 includes component removal 500. Component removal 500 can include the utilization of high vacuum, and/or mechanical clamping to physically adhere to and lift a component from the circuit board before the solder or adhesive is melted/cured. Still another form of mechanical interaction is the control of the vacuum pressure that is used to pick up the component. As the speed of the pick and place operation increases, it is advantageous to turn the vacuum on and off close to the tip of the nozzle so that the component can be released from the nozzle quickly. Still another form of mechanical interaction 496 includes the selective or isolated curing 502 of solder or adhesive. Yet another form of mechanical interaction 496 is the marking 504 of a component. Marking 504 can simply take the form of the marking of a component that has a failed a particular inspection and should be addressed later in the assembly process by a rework technician. Other forms of marking can include the utilization of inkjet technology to deliver indicia to an exposed surface of the component or circuit board to provide information relative to the electronics assembly operation and/or the component itself. Mechanical interaction 496 can also include deposition 506 of solder paste or adhesive. Thus, in the example given above where a defective component is removed from a circuit board, new or replacement solder paste can be automatically delivered to the location of the removed component to prepare that location for the arrival for a replacement component. As can be appreciated, output module 482 can certainty include other forms of outputs that can direct a physical interaction upon the component, or circuit board.

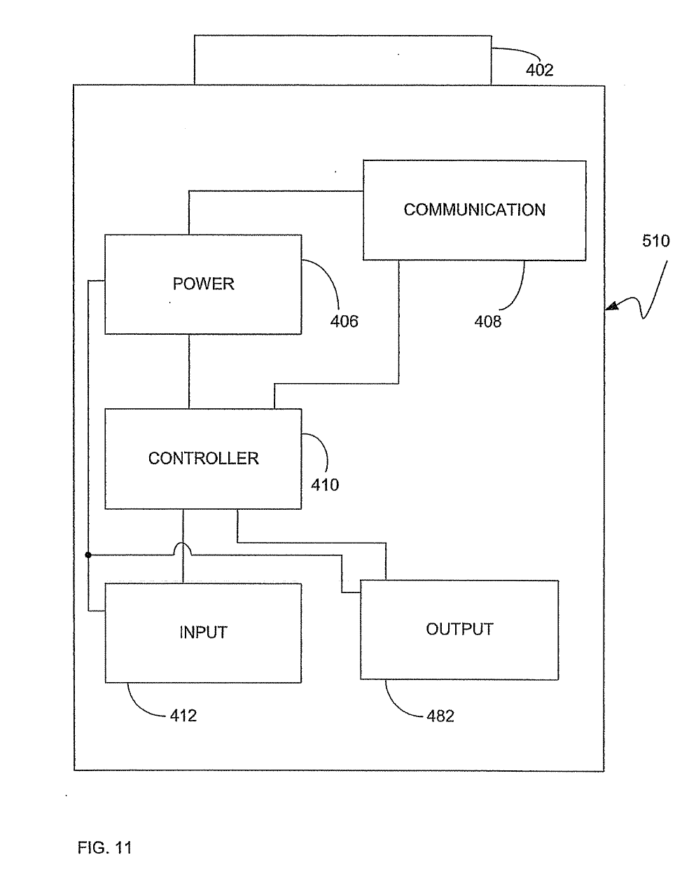

FIG. 11 is a diagrammatic view of yet another detachable nozzle having wireless communication in accordance with an embodiment of the present invention. Nozzle 510 illustrates that embodiments of the present invention can include both input circuitry 412 as well as output circuitry 482. While it is preferred that embodiments of the present invention generally communicate wirelessly with the pick and place machine, or other suitable external devices, it is also expressly contemplated that at least some of the inputs or sensing performed by the detachable nozzles can be stored in memory 411, which stored information can later by uploaded from the detachable nozzle when the detachable nozzle is replaced in its storage rack or bin. Accordingly, the physical cooperation between the detachable nozzles in accordance with embodiments of the present invention and their respective charging/retaining cradles not only can provide power to recharge the nozzles, but also communication channels to retrieve the stored data.

Although the present invention has been described with reference to preferred embodiments, workers skilled in the art will recognize that changes may be made in form and detail without departing from the spirit and scope of the invention.

What is claimed is:

1. A pick and place machine for placing components upon a workpiece, the pick and place machine comprising:
a placement head;
a robotic system configured to generate relative movement between the placement head and the workpiece; and
at least one detachable nozzle coupled to the placement head, the detachable nozzle having wireless communication circuitry.

2. The pick and place machine of claim 1, wherein the at least one detachable nozzle further comprises:
input circuitry; and
a controller coupled to the input circuitry and to the wireless communication circuitry, wherein the controller is configured to communicate information through the wireless communication circuitry based upon information received from the input circuitry.

3. The pick and place machine of claim 2, wherein the input circuitry includes circuits to sense a parameter of the pick and place machine.

4. The pick and place machine of claim 2, wherein the input circuitry includes circuits to sense an environmental variable.

5. The pick and place machine of claim 2, wherein the input circuitry includes circuits to test a component.

6. The pick and place machine of claim 2, wherein the input circuitry includes circuits to test a workpiece.

7. The pick and place machine of claim 1, wherein the wireless communication circuitry includes radio-frequency (RF) communication circuitry.

8. The pick and place machine of claim 1, wherein the wireless communication circuitry includes optical communication circuitry.

9. The pick and place machine of claim 1, and further comprising identification information.

10. The pick and place machine of claim 9, wherein the identification information is computer-readable information.

11. The pick and place machine of claim 1, wherein the at least one detachable nozzle further comprises:
output circuitry; and
a controller coupled to the output circuitry and to the wireless communication circuitry, wherein the controller is configured to communicate information through the wireless communication circuitry and to generate a physical output via the output circuitry.

12. The pick and place machine of claim 11, wherein the output circuitry is configured to deliver a physical interaction.

13. The pick and place machine of claim 12, wherein the physical interaction includes generating illumination.

14. The pick and place machine of claim 12, wherein the physical interaction includes mechanical interaction.

15. The pick and place machine of claim 12, wherein the physical interaction includes electrical interaction.

16. The pick and place machine of claim 1, wherein the detachable nozzle further comprises a power module configured to power the nozzle.

17. The pick and place and place machine of claim 16, wherein the power module includes a battery.

18. The pick and place machine of claim 17, wherein the battery is a rechargeable battery.

19. A detachable nozzle for use in a pick and place machine, the nozzle comprising:
an engagement portion configure to removably attach to a placement head of a pick and place machine;
a nozzle body coupled to the engagement portion; and
wireless communication circuitry disposed within the nozzle body and configured to interact wirelessly with another wireless device disposed remote from the detachable nozzle.

20. The nozzle of claim 19, and further comprising:
input circuitry; and
a controller coupled to the input circuitry and to the wireless communication circuitry, wherein the controller is configured to communicate information through the wireless communication circuitry based upon information received from the input circuitry.

21. The nozzle of claim 20, wherein the input circuitry includes circuits to sense a parameter of the pick and place machine.

22. The nozzle of claim 20, wherein the input circuitry includes circuits to sense an environmental variable.

23. The nozzle of claim 20, wherein the input circuitry includes circuits to test a component.

24. The nozzle of claim 20, wherein the input circuitry includes circuits to test a workpiece.

25. The nozzle of claim 19, wherein the wireless communication circuitry includes radio-frequency (RF) communication circuitry.

26. The nozzle of claim 19, wherein the wireless communication circuitry includes optical communication circuitry.

27. The nozzle of claim 19, and further comprising identification information.

28. The nozzle of claim 27, wherein the identification information is computer-readable information.

29. The nozzle of claim 19, wherein the at least one detachable nozzle further comprises:
output circuitry, and
a controller coupled to the output circuitry and to the wireless communication circuitry, wherein the controller is configured to communicate information through the wireless communication circuitry and to generate a physical output via the output circuitry.

30. The nozzle of claim 29, wherein the output circuitry is configured to deliver a physical interaction.

31. The nozzle of claim 30, wherein the physical interaction includes generating illumination.

32. The nozzle of claim 30, wherein the physical interaction includes mechanical interaction.

33. The nozzle of claim 30, wherein the physical interaction includes electrical interaction.

34. The nozzle of claim 19, and further comprising a power module configured to power the nozzle.

35. The nozzle of claim 34, wherein the power module includes a battery.

36. The nozzle of claim 35, wherein the battery is a rechargeable battery.
